(19) United States
(12) Patent Application Publication
(10) Pub. No.: US 2026/0309655 A1
(43) Pub. Date: Oct. 8, 2026

(54) METHOD FOR MEASURING DEFECTS IN TWO-COMPONENT COMPOUND WAFER AND APPARATUS THEREOF

(71) Applicant: SK SILTRON CO., LTD., Gumi-si (KR)

(72) Inventors: Won Jun LEE, Gumi-si (KR); Seob SHIM, Gumi-si (KR); Woo Sung LEE, Gumi-si (KR)

(21) Appl. No.: 19/532,168

(22) Filed: Feb. 6, 2026

(30) Foreign Application Priority Data
Apr. 4, 2025 (KR) 10-2025-0044049

(51) Int. Cl. G01N 23/2273; G01N 23/18; G01N 23/2251

(52) U.S. Cl. CPC G01N 23/2273; G01N 23/18; G01N 23/2251; G01N 2223/6116

(57) ABSTRACT

The present embodiment relates to a method for measuring defects in two-component compound wafer capable of detecting P-Count ScN defects in a two-component compound wafer using a highly accurate quantitative measurement method, and an apparatus thereof.

According to one aspect of the embodiment, a method for measuring defects in a two-component compound wafer is provided, and the method includes a first step of measuring content of matrix A elements and matrix B elements in a wafer composed of the matrix A elements and the matrix B elements; and a second step of calculating a ratio of the matrix A elements and the matrix B elements measured in the first step to determine a P-Count ScN defect level.

### CROSS-REFERENCE TO RELATED APPLICATION

The subject application claims priority to Korean Patent Application Number 10-2025-0044049, filed on Apr. 4, 2025, the entire content of which is incorporated herein by reference.

### BACKGROUND

The present embodiment relates to a method for measuring defects in two-component compound wafer capable of detecting P-Count ScN defects in a two-component compound wafer using a highly accurate quantitative measurement method, and an apparatus thereof.

The wafer manufacturing process consists of a single crystal growth process to create a single crystal ingot, a slicing process to slice the single crystal ingot into a thin, disc-shaped wafer, a grinding process to machine an outer peripheral portion of the wafer to prevent breakage and distortion obtained through the slicing process, a lapping process to remove any remaining mechanical damage to the wafer, a polishing process to mirror the wafer surface, and a cleaning process to polish the polished wafer and remove any abrasives or foreign substances attached to the wafer.

Due to the growth process and other factors, wafers may develop surface defects such as crystal defects, particles, pits, or juts on the surface.

Since the above-described crystal defects or surface defects affect the device yield and quality, it is necessary to completely remove crystal defects or surface defects and to quickly and easily evaluate these defects.

Among the above-described crystal defects, one type of defect detected in a two-component compound semiconductor wafer is the P-Count ScN defect, and this defect is a near-surface or near-bulk defect that can only be measured and observed in the ScN (Scattering Normal) channel of a measurement and metrology equipment commonly referred to as P-Count. These P-Count ScN defects can be classified as killer defects that reduce device yield during the yield testing process after device fabrication.

FIG. 1 is a diagram illustrating a P-Count ScN defect in a two-component compound wafer observed with a P-Count equipment.

As illustrated in FIG. 1, P-Count ScN defects are clearly observed as laser scattering signals from the P-Count equipment.

However, while attempts have been made to analyze P-Count ScN defects intuitively using electron microscopy, no analytical method exists that can clearly observe or identify and define significant differences other than the P-Count equipment. In other words, since P-Count equipment can only provide information on the extent to which P-Count ScN defects exist within the two-component compound wafer plane, there is no clear analytical data on P-Count ScN defects.

Therefore, research is needed to develop a method that can detect P-Count ScN defects with high accuracy, considering the properties and characteristics of the P-Count ScN defects.

### SUMMARY

An object of the present embodiment is to solve the above-described problems and other problems.

Another object of the present embodiment is to provide a method for measuring defects in a two-component compound wafer capable of detecting P-Count ScN defects in a two-component compound wafer using a highly accurate quantitative measurement method, and an apparatus thereof.

According to one aspect of the embodiment, a method for measuring defects in a two-component compound wafer is provided, the method includes a first step of measuring content of matrix A elements and matrix B elements in a wafer composed of the matrix A elements and the matrix B elements; and a second step of calculating a ratio of the matrix A elements and the matrix B elements measured in the first step to determine a P-Count ScN defect level.

According to one aspect of the embodiment, the first step may include a process of determining the presence or absence of a P-Count ScN defect in the wafer using a P-Count apparatus.

According to one aspect of the embodiment, the first step may include a process of sampling the specimen in a rectangular shape with a maximum width of 20 mm and a maximum length of 20 mm.

According to one aspect of the embodiment, in the first step, the sampling of the specimen may be performed in a clean room to prevent surface contamination of the specimen.

According to one aspect of the embodiment, the second step may measure the content of the matrix A element and the matrix B element using X-ray photoelectron spectroscopy (XPS).

According to one aspect of the embodiment, the second step may include a process of excluding elements other than the matrix A element and the matrix B element from the surface of the specimen as noise by scanning the specimen with a first acceleration energy.

According to one aspect of the embodiment, the second step may further include a process of measuring the contents of the matrix A element and the matrix B element by scanning the specimen with a high-resolution X-ray having a spot size of 200 μm or less at a second acceleration energy higher than the first acceleration energy.

According to one aspect of the embodiment, the second step may include a process of calculating a component content ratio (B/A) of the matrix B element to the matrix A element; and a process of determining that the P-Count ScN defect level is high if the component content ratio (B/A) is a preset reference value or more.

According to one aspect of the embodiment, the method for measuring defects in a two-component compound wafer may further include a third step of analyzing the sampled specimen from the second step using a scanning electron microscope (SEM) or a transmission electron microscope (TEM); and a fourth step of confirming the defect as a P-Count ScN defect by matching the analysis results from the second step with the analysis results from the third step.

According to another aspect of the embodiment, an apparatus for measuring defects in a two-component compound wafer is provided, and the apparatus includes a measuring part configured to measure the content of matrix A elements and matrix B elements in a wafer composed of the matrix A elements and the matrix B elements; and a control part configured to calculate the ratio of the matrix A elements and the matrix B elements measured by the measuring part to determine a P-Count ScN defect level.

According to another aspect of the embodiment, the measuring part may measure the contents of the matrix A element and the matrix B element using X-ray photoelectron spectroscopy (XPS).

According to another aspect of the embodiment, the measuring part may exclude elements other than the matrix A element and the matrix B element from the surface of the specimen as noise by scanning the specimen with a first acceleration energy.

According to another aspect of the embodiment, the measuring part may measure the contents of the matrix A element and the matrix B element by scanning the specimen with a high-resolution X-ray having a spot size of 200 μm or less at a second acceleration energy higher than the first acceleration energy.

According to another aspect of the embodiment, the control part may calculate the component content ratio (B/A) of the matrix B element to the matrix A element and determine that the P-Count ScN defect level is high if the component content ratio (B/A) is a preset reference value or more.

According to another aspect of the embodiment, the apparatus for measuring defect in a two-component compound wafer may further include an electron microscope configured to analyze P-Count ScN defects in the wafer measured by the measuring part; in which the control part may confirm P-Count ScN defects by matching the analysis results of the electron microscope with the analysis results of the measuring part.

According to the present embodiment, since the P-Count ScN defect can be accurately measured and evaluated quantitatively according to the element content ratio constituting the two-component compound wafer, there is an advantage of being able to prevent yield loss in the device process due to the P-Count ScN defect in advance and to improve reliability of wafer quality.

### BRIEF DESCRIPTION OF THE DRAWINGS

FIG. 1 is a diagram illustrating P-Count ScN defects in a two-component compound wafer observed with a P-Count equipment.

FIG. 2 is a flowchart illustrating a method for measuring defects in a two-component compound wafer according to an embodiment.

FIG. 3 is a diagram illustrating P-Count ScN defects in a two-component compound wafer according to an embodiment.

FIG. 4 is a diagram illustrating a specimen sampling process in a two-component compound wafer according to an embodiment.

FIG. 5 is a graph illustrating the contents of elements A and B in a two-component compound wafer according to an embodiment.

FIG. 6 is a graph illustrating the B/A content ratio in a two-component compound wafer according to an embodiment.

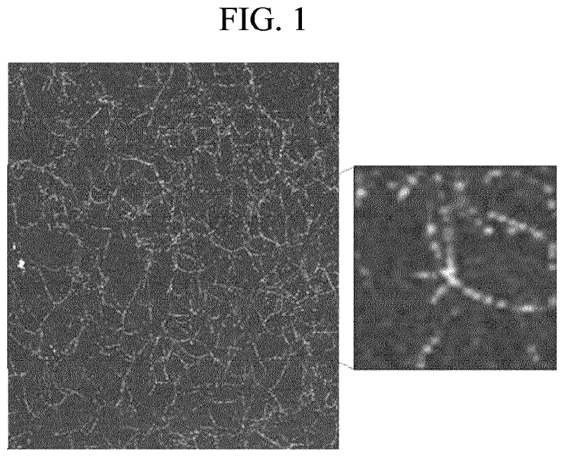

### DETAILED DESCRIPTION OF THE EMBODIMENTS

Below, the present embodiment will be examined in detail with reference to the attached drawings.

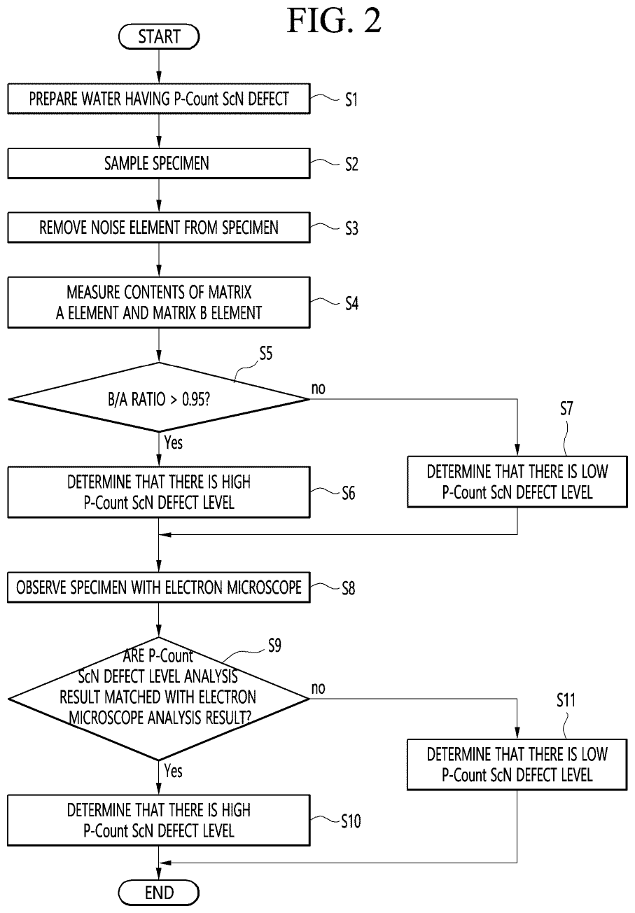

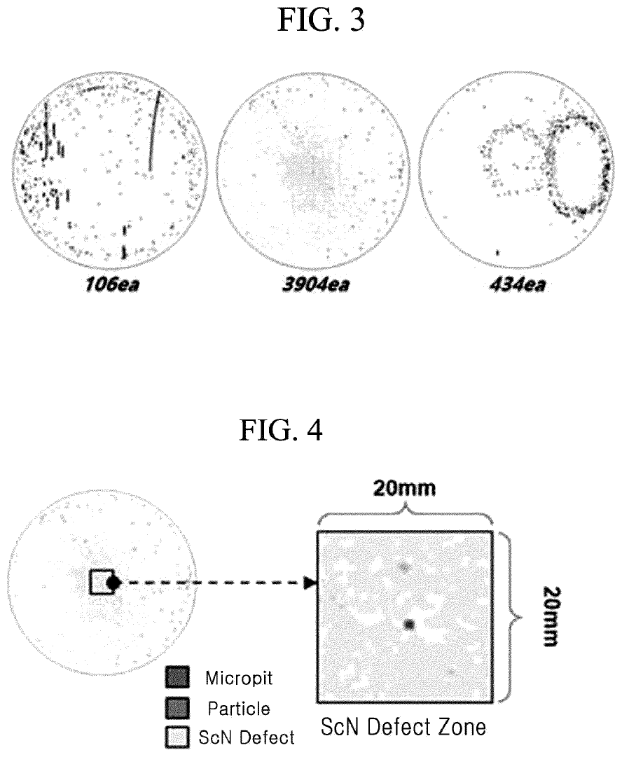

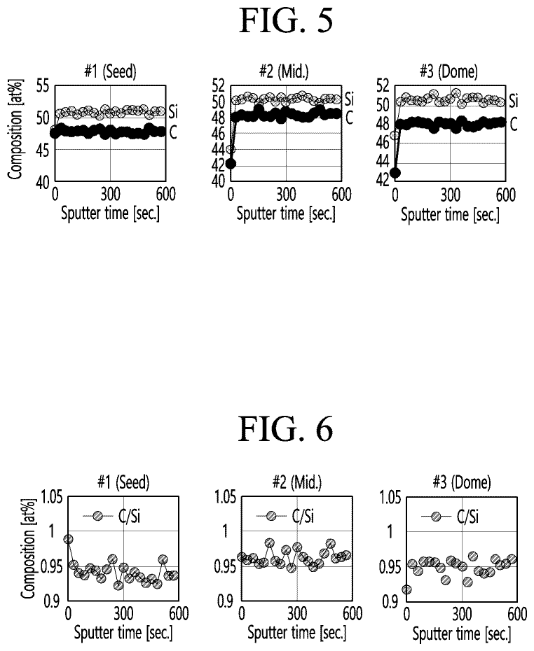

FIG. 2 is a flowchart illustrating a method for measuring defects in a two-component compound wafer according to an embodiment, FIG. 3 is a diagram illustrating P-Count ScN defects in a two-component compound wafer according to an embodiment, FIG. 4 is a diagram illustrating a specimen sampling process in a two-component compound wafer according to an embodiment, FIG. 5 is a graph illustrating the contents of elements A and B in a two-component compound wafer according to an embodiment, and FIG. 6 is a graph illustrating the B/A content ratio in a two-component compound wafer according to an embodiment.

According to a method for measuring defects in a two-component compound wafer according to an embodiment, a wafer having a P-Count ScN defect is prepared among wafers containing a matrix A element and a matrix B element, as illustrated in FIG. 2 (see S1).

The matrix A element is the element with the larger atomic mass among the two elements forming the two-component compound, and the matrix A element may refer to an element with a larger atomic mass than the matrix B element. The matrix A element and the matrix B element are not particularly limited. As illustrated in FIG. 3, the presence and number of P-Count ScN defects in the two-component compound wafer can be counted based on the Map Image results measured using a P-Count apparatus. Even if a P-Count ScN defect is observed when measured using a P-Count apparatus, the P-Count ScN defect may not be an actual defect. Since P-Count ScN defects are believed to be caused by stress and strain due to the temperature gradient occurring during the growth of the two-component compounds, a high-resolution analysis of the matrix elements A and B constituting the two-component compounds is conducted to identify P-Count ScN defects.

Next, the area of the wafer where P-Count ScN defects exist is sampled as a specimen (see S2).

As illustrated in FIG. 4, the specimen can be sampled in a rectangular shape with a maximum width of 20 mm and a maximum length of 20 mm from the P-Count ScN defect area in a two-component compound wafer, and to prevent surface contamination of the specimen, this process is preferably performed in a clean room.

Next, X-ray photoelectron spectroscopy (XPS) is used to remove noise elements from the specimen and measure the content of matrix A and matrix B elements (see S3 and S4).

XPS is a non-destructive analysis method, irradiates the specimen surface with X-rays, measures the energy of photoelectrons generated when outer electrons break bonds to analyze information on the composition and chemical bonding of the specimen surface and also allows for depth profile measurement.

Using XPS, the surface of the specimen is scanned repeatedly with X-rays set to a relatively low first acceleration energy, and thus this process allows for the exclusion of elements other than A and B as noise. Afterwards, by using XPS, the surface of the specimen is scanned with a high-resolution X-ray having a spot size of 200 μm or less, which is a size at which P-Count ScN defects can be detected, by setting the second acceleration energy to be relatively higher than the first acceleration energy, and thus the contents of matrix A and matrix B elements can be measured using precise measurement according to the depth profile.

When growing a two-component compound ingot from a raw material melt, the content of elements A and B varies according to the axial position of the two-component compound ingot. As illustrated in FIG. 5, the initial wafer (#1.Seed) made in the early stages of the growth of the two-component compound (AB) ingot illustrates an A element content of 50.97% and a B element content of 47.86%, the wafer (#2.Mid) made in the middle stages of the growth of the two-component compound (AB) ingot illustrates an A element content of 50.34% and a B element content of 48.45%, and the wafer (#3.Dome) made in the latter stages of the growth of the two-component compound (AB) ingot illustrates an A element content of 50.59% and a B element content of 47.06%.

Next, if the content ratio of the matrix A element and the matrix B element exceeds 0.95, the P-Count ScN defect level is determined to be high, but if the content ratio of the matrix A element and the matrix B element is the above-described reference value or less, the P-Count ScN defect level is determined to be low (Refer to S5, S6, S7).

Here, the reference value may vary according to the types of matrix elements A and B, and may be 0.95 in one embodiment.

As illustrated in FIG. 6, the initial wafer (#1.Seed) made in the early stages of growth of the two-component compound (AB) ingot has a low P-Count ScN defect level and a low B/A content ratio of 0.94. On the other hand, the wafer (#2.Mid) made in the middle stages of growth of the two-component compound (AB) ingot has a high P-Count ScN defect level and a high B/A content ratio of 0.96. On the other hand, the wafer (#3.Dome) made in the latter stages of growth of the two-component compound (AB) ingot has a moderate P-Count ScN defect level and a medium B/A content ratio of 0.95. In other words, the P-Count ScN defect level can be determined based on the B/A content ratio.

Next, to verify that the P-Count ScN defect level is determined based on the B/A content ratio in the sampled specimens from the two-component (AB) wafer, the specimens are observed under an electron microscope (see S8).

Electron microscopy can include a scanning electron microscope (SEM) or a transmission electron microscope (TEM) as a destructive analysis method. SEM has a resolution of 0.005 μm and a magnification of approximately 800,000×, while TEM has a resolution of 0.0002 μm and a magnification of approximately 1,000,000×, allowing the identification of P-Count ScN defects in specimens.

Next, if the P-Count ScN defect level analysis results based on the element content ratio (B/A) match the electron microscopy analysis results, the P-Count ScN defect level is confirmed to be high, and otherwise, the P-Count ScN defect level is confirmed to be low. (See S9, S10, and S11.)

As such, since the P-Count ScN defects observed by P-Count may not be actual defects, XPS can accurately and easily determine the P-Count ScN defect level based on the element content ratio, and while the XPS analysis results can be used to confirm the P-Count ScN defects using electron microscopy, the process of confirming the P-Count ScN defects using electron microscopy can be omitted.

The above description merely exemplifies the technical ideas of the present disclosure, and those skilled in the art will appreciate that various modifications and variations can be made without departing from the essential characteristics of the present disclosure.

Therefore, the embodiments disclosed in the present disclosure are intended to illustrate, rather than limit, the technical ideas of the present disclosure, and these embodiments do not limit the scope of the technical ideas of the present disclosure.

The scope of protection of the present disclosure should be interpreted according to the following claims, and all technical ideas within the scope equivalent thereto should be construed as being included within the scope of the rights of the present disclosure.

What is claimed is:

1. A method for measuring defects in a two-component compound wafer, comprising:
a first step of measuring content of matrix A elements and matrix B elements in a wafer composed of the matrix A elements and the matrix B elements; and
a second step of calculating a ratio of the matrix A elements and the matrix B elements measured in the first step to determine a P-Count ScN defect level.

2. The method for measuring defects in a two-component compound wafer of claim 1,
wherein the first step includes:
a process of determining the presence or absence of a P-Count ScN defect in the wafer using a P-Count apparatus; and
a process of sampling an area of the wafer where a P-Count ScN defect exists as a specimen.

3. The method for measuring defects in a two-component compound wafer of claim 2,
wherein, in the first step, the specimen is sampled in a rectangular shape with a maximum width of 20 mm and a maximum length of 20 mm.

4. The method for measuring defects in a two-component compound wafer of claim 2,
wherein, in the first step, the sampling of the specimen is performed in a clean room to prevent surface contamination of the specimen.

5. The method for measuring defects in a two-component compound wafer of claim 1,
wherein the first step includes a process of measuring the content of the matrix A element and the matrix B element using X-ray photoelectron spectroscopy (XPS).

6. The method for measuring defects in a two-component compound wafer of claim 5,
wherein the first step includes a process of excluding elements other than the matrix A element and the matrix B element from the surface of the specimen as noise by scanning the specimen with a first acceleration energy.

7. The method for measuring defects in a two-component compound wafer of claim 6,
wherein the first step further includes a process of measuring the contents of the matrix A element and the matrix B element by scanning the specimen with a high-resolution X-ray having a spot size of 200 μm or less at a second acceleration energy higher than the first acceleration energy.

8. The method for measuring defects in a two-component compound wafer of claim 1,
wherein the second step includes:
a process of calculating a component content ratio (B/A) of the matrix B element to the matrix A element; and
a process of determining that the P-Count ScN defect level is high if the component content ratio (B/A) is a preset reference value or more.

9. The method for measuring defects in a two-component compound wafer of claim 1, further comprising:
a third step of analyzing the sampled specimen from the first step using a scanning electron microscope (SEM) or a transmission electron microscope (TEM); and
a fourth step of confirming the defect as a P-Count ScN defect by matching the analysis results from the second step with the analysis results from the third step.

10. An apparatus for measuring defects in a two-component compound wafer, comprising:
a measuring part configured to measure the content of matrix A elements and matrix B elements in a wafer composed of the matrix A elements and the matrix B elements; and
a control part configured to calculate the ratio of the matrix A elements and the matrix B elements measured by the measuring part to determine a P-Count ScN defect level.

11. The apparatus for measuring defects in a two-component compound wafer of claim 10,
wherein the measuring part measures the contents of the matrix A element and the matrix B element using X-ray photoelectron spectroscopy (XPS).

12. The apparatus for measuring defects in a two-component compound wafer of claim 10,
wherein the measuring part excludes elements other than the matrix A element and the matrix B element from the surface of the specimen as noise by scanning the specimen with a first acceleration energy.

13. The apparatus for measuring defects in a two-component compound wafer of claim 12,
wherein the measuring part measures the contents of the matrix A element and the matrix B element by scanning the specimen with a high-resolution X-ray having a spot size of 200 μm or less at a second acceleration energy higher than the first acceleration energy.

14. The apparatus for measuring defects in a two-component compound wafer of claim 10,
wherein the control part calculates the component content ratio (B/A) of the matrix B element to the matrix A element and determines that the P-Count ScN defect level is high if the component content ratio (B/A) is a preset reference value or more.

15. The apparatus for measuring defect in a two-component compound wafer of claim 10, further comprising:
an electron microscope configured to analyze P-Count ScN defects in the wafer measured by the measuring part;
wherein the control part confirms P-Count ScN defects by matching the analysis results of the electron microscope with the analysis results of the measuring part.
